(19) United States
(12) Patent Application Publication
(10) Pub. No.: US 2005/0031799 A1
(43) Pub. Date: Feb. 10, 2005

(54) Process for preparing radiation image storage panel

(75) Inventors: Hiroshi Matsumoto, Kanagawa (JP); Atsunori Takasu, Kanagawa (JP); Yuji Isoda, Kanagawa (JP)

Correspondence Address: LAURENCE A WEINBERGER, 882 S. MATLACK ST., SUITE 103, WEST CHESTER, PA, 19382, US

(73) Assignee: FUJI PHOTO FILM CO., LTD.

(21) Appl. No.: 10/874,307

(22) Filed: Jun. 24, 2004

(30) Foreign Application Priority Data
Jun. 25, 2003 (JP) 2003-181612

(51) Int. Cl. C23C 16/00

(52) U.S. Cl. 427/593; 427/249.1

(57) ABSTRACT

An improvement of a process for preparing a radiation image storage panel by heating an evaporation source containing a phosphor in a deposition apparatus to produce its vapor and depositing the vapor on a substrate to form a phosphor layer resides in that the heating and depositing are performed under such condition that an inert gas is introduced into the apparatus at a flow rate of Vn satisfying the following condition, while the apparatus is being evacuated,
0.002≦Vn/Vc≦20 [Vn is a flow rate in terms of mL/min., and Vc is a volume of the apparatus in terms of L].

### FIELD OF THE INVENTION

The present invention relates to a process for preparing a radiation image storage panel employable in a radiation image recording and reproducing method which utilizes an energy-storing phosphor.

### BACKGROUND OF THE INVENTION

When exposed to radiation such as X-rays, an energy-storing phosphor (e.g., stimulable phosphor, which gives stimulated emission off) absorbs and stores a portion of the radiation energy. The phosphor then produces stimulated emission according to the level of the stored energy when exposed to electromagnetic wave such as visible or infrared light (i.e., stimulating light). A radiation image recording and reproducing method utilizing the energy-storing phosphor has been widely employed in practice. In that method, a radiation image storage panel, which is a sheet comprising the energy-storing phosphor, is used. The method comprises the steps of: exposing the storage panel to radiation having passed through an object or having radiated from an object, so that radiation image information of the object is temporarily recorded in the panel; sequentially scanning the panel with a stimulating light such as a laser beam to emit a stimulated light; and photoelectrically detecting the emitted light to obtain electric image signals. The storage panel thus treated is subjected to a step for erasing radiation energy remaining therein, and then stored for the use in the next recording and reproducing procedure. Thus, the radiation image storage panel can be repeatedly used.

The radiation image storage panel (often referred to as energy-storing phosphor sheet) has a basic structure comprising a support and an energy-storing phosphor layer provided thereon. If the phosphor layer is self-supporting, the support may be omitted. Further, a protective film is ordinarily placed on the free surface (surface not facing the support) of the phosphor layer to keep the phosphor layer from chemical or physical damage.

The phosphor layer usually comprises a binder and an energy-storing phosphor dispersed therein. However, the phosphor layer may comprise an agglomerate of an energy-storing phosphor without binder, and such phosphor layer is already known. The phosphor layer containing no binder can be formed by a vapor phase deposition method or by a firing method. Further, the phosphor layer may comprise energy-storing phosphor agglomerate impregnated with a polymer material, which also is already known.

JP-A-2001-255610 discloses a variation of the radiation image recording and reproducing method. While an energy-storing phosphor of the storage panel used in the ordinary method plays both roles of radiation-absorbing function and energy-storing function, those two functions are separated in the disclosed method. In the method, a radiation image storage panel comprising an energy-storing phosphor (which stores radiation energy) is used in combination with a phosphor screen comprising another phosphor which absorbs radiation and emits ultraviolet or visible light. The disclosed method comprises the steps of causing the radiation-absorbing phosphor of the screen (and of the panel) to absorb and convert radiation having passed through an object or having radiated from an object into ultraviolet or visible light; causing the energy -storing phosphor of the panel to store the energy of the converted light as radiation image information; sequentially exciting the energy-storing phosphor with a stimulating ray to emit stimulated light; and photoelectrically detecting the emitted light to obtain electric signals giving a visible radiation image. The present invention can be also applied to the radiation image storage panel used in this type of the method.

The radiation image recording and reproducing method (or radiation image forming method) has various advantages as described above. However, it is still desired that the radiation image storage panel used in the method has as high sensitivity as possible and, at the same time, gives a reproduced radiation image of high quality (in regard to sharpness and graininess).

In order to improve the sensitivity and the image quality, it is proposed that the phosphor layer of the storage panel be prepared by a gas phase-accumulation method such as vacuum vapor deposition or sputtering. The process of vacuum vapor deposition, for example, comprises the steps of: heating to vaporize an evaporation source comprising a phosphor or components thereof utilizing a resistance heater or an electron beam, and depositing and accumulating the vapor on a substrate such as a metal sheet to form a layer of the phosphor in the form of columnar crystals.

The phosphor layer formed by the gas phase-accumulation method contains no binder and consists of the phosphor only, and there are cracks between the columnar crystals of the phosphor. Because of these cracks, the stimulating light can stimulate the phosphor efficiently and the emitted light can be collected efficiently, too. Accordingly, a radiation image storage panel having the phosphor layer formed by the gas phase-accumulation method has high sensitivity. At the same time, since the cracks prevent the stimulating light from diffusing parallel to the layer, the storage panel can give a reproduced image of high sharpness.

JP-A-2001-249198 discloses a process for preparation of a storage phosphor screen containing no binder. In the process, an alkali metal storage phosphor or precursor thereof is vaporized and deposited on a substrate under Ar gas atmosphere of 3 Pa or less while the substrate is heated at a temperature of 50 to 300° C. In an example described in the publication, a deposited layer of CsBr:Eu phosphor was formed while Ar gas was introduced into the deposition apparatus and then evacuated with a vacuum pump. However, how much Ar gas was introduced is not concretely disclosed in the publication.

### SUMMARY OF THE INVENTION

The present inventors have studied the deposition process for forming a phosphor layer of radiation image storage panel, and found that, during the step of deposition, gas components (particularly, active gas components such as H₂O, O₂ and H₂ gases) beforehand adsorbed on the inner wall of the deposition apparatus are released continuously and, as a result, that the released gas components often give unfavorable effects to characteristics of the deposited layer, particularly, to the amount of stimulated emission given off from the deposited layer. This problem is important particularly when the deposition procedure is performed under a medium degree of vacuum (approx. 0.05 to 10 Pa), for example, by means of a resistance heater. The inventors have further studied to solve the problem, and finally achieved the present invention, by which the active gas components can-be prevented from increasing in the deposition atmosphere by keeping a predetermined specific degree of vacuum. In the present invention, a predetermined amount of inert gas is continuously introduced into the apparatus while the apparatus is evacuated so as to ventilate the deposition atmosphere constantly.

It is an object of the present invention to provide a process for preparation of a radiation image storage panel improved in sensitivity.

The present invention resides in a process for preparing a radiation image storage panel which comprises the steps of heating an evaporation source containing a phosphor or components thereof in a deposition apparatus to produce a vapor thereof and depositing the vapor on a substrate to form a phosphor layer thereon, wherein the steps are performed under such condition that an inert gas is introduced into the apparatus at a flow rate of Vn satisfying the following condition, while the apparatus is being evacuated,
0.002≦Vn/Vc≦20
in which Vn is a flow rate of the gas introduced into the apparatus in terms of mL/min., and Vc is a volume of the apparatus in terms of L.

### BRIEF DESCRIPTION OF DRAWING

FIGURE is a sectional view schematically illustrating a deposition apparatus used in the invention.

### DETAILED DESCRIPTION OF THE INVENTION

Preferred embodiments of the present invention are as follows.

(1) The degree of vacuum in the apparatus is kept in the range of 0.05 to 10 Pa during the step of heating and deposition.

(2) The flow Vn of the inert gas satisfies the condition of: 0.005≦Vn/Vc≦10.

(3) The inert gas is Ar gas.

(4) The deposition is conducted utilizing a resistance heater.

(5) The partial pressure of H₂O in the apparatus is kept at 2×10⁻² Pa or less during the step of deposition.

(6) The partial pressure of O₂ in the apparatus is kept at 1×10⁻³ Pa or less during the step of deposition.

(7) The partial pressure of H₂ in the apparatus is kept at 1×10⁻² Pa or less during the step of deposition.

(8) The phosphor is an energy-storing phosphor, particularly, a stimulable alkali metal halide phosphor represented by the following formula (I):
M^{I}X.aM^{II}X′₂.bM^{III}X″₃:zA (I)
in which M^{I} is at least one alkali metal selected from the group consisting of Li, Na, K, Rb and Cs; M^{II} is at least one alkaline earth metal or divalent metal selected from the group consisting of Be, Mg, Ca, Sr, Ba, Ni, Cu, Zn and Cd; M^{III} is at least one rare earth element or trivalent metal selected from the group consisting of Sc, Y, La, Ce, Pr, Nd, Pm, Sm, Eu, Gd, Tb, Dy, Ho, Er, Tm, Yb, Lu, Al, Ga and In; each of X, X′ and X″ is independently at least one halogen selected from the group consisting of F, Cl, Br and I; A is at least one rare earth element or metal selected from the group consisting of Y, Ce, Pr, Nd, Sm, Eu, Gd, Tb, Dy, Ho, Er, Tm, Yb, Lu, Na, Mg, Cu, Ag, Tl and Bi; and a, b and z are numbers satisfying the conditions of 0≦a<0.5, 0≦b<0.5 and 0<z<1.0, respectively.

(9) In the formula (I), M^{I}, X and A are Cs, Br and Eu, respectively, and z is a number satisfying the condition of 1×10⁻⁴≦z≦0.1.

In the following description, the process of the invention for preparing a radiation image storage panel is explained in detail, by way of example, in the case where a resistance-heating process is adopted. The resistance -heating process can be carried out under medium vacuum, and thereby a preferred columnar crystal-deposited layer can be easily formed.

The substrate on which the vapor is deposited is that which is ordinarily used as a support of the radiation image storage panel, and hence can be optionally selected from known materials conventionally used as supports of a storage panel. The substrate preferably is a sheet of quartz glass, sapphire glass; metal such as aluminum, iron, tin or chromium; or heat-resistant resin such as aramide. For improving the sensitivity or the image quality (e.g., sharpness and graininess), a conventional radiation image storage panel often has a light-reflecting layer containing a light reflecting material such as titanium dioxide or a light-absorbing layer containing a light-absorbing material such as carbon black. These auxiliary layers can be provided on the storage panel of the invention, if needed. Further, in order to promote growth of the columnar crystals, a great number of very small convexes or concaves may be provided on the substrate surface on which the vapor is deposited. If an auxiliary layer such as a subbing layer (adhesive layer), a light-reflecting layer or a light-absorbing layer is formed on the deposited-side surface of the substrate, the convexes or concaves may be provided on the surface of the auxiliary layer.

The phosphor preferably is an energy-storing phosphor, more preferably a stimulable phosphor giving stimulated emission off in the wavelength region of 300 to 500 nm when exposed to a stimulating light in the wavelength region of 400 to 900 nm.

The phosphor particularly preferably is a stimulable alkali metal halide phosphor represented by the following formula (I):
M^{I}X.aM^{II}X′₂.bM^{III}X″₃:zA (I).
In the formula (I), M^{I} is at least one alkali metal selected from the group consisting of Li, Na, K, Rb and Cs; M^{II} is at least one alkaline earth metal or divalent metal selected from the group consisting of Be, Mg, Ca, Sr, Ba, Ni, Cu, Zn and Cd; M^{III} is at least one rare earth element or trivalent metal selected from the group consisting of Sc, Y, La, Ce, Pr, Nd, Pm, Sm, Eu, Gd, Tb, Dy, Ho, Er, Tm, Yb, Lu, Al, Ga and In; each of X, X′ and X″ is independently at least one halogen selected from the group consisting of F, Cl, Br and I; A is at least one rare earth element or metal selected from the group consisting of Y, Ce, Pr, Nd, Sm, Eu, Gd, Tb, Dy, Ho, Er, Tm, Yb, Lu, Na, Mg, Cu, Ag, Tl and Bi; and a, b and z are numbers satisfying the conditions of 0≦a<0.5, 0≦b<0.5 and 0<z<1.0, respectively.

In the formula (I), M^{I}preferably comprises at least Cs, X preferably comprises at least Br, A preferably is Eu or Bi, and z preferably satisfies the condition of 1×10⁻⁴≦z≦0.1.

The phosphor represented by the formula (I) may further comprise, if needed, metal oxides such as aluminum oxide, silicone oxide and zirconium oxide as additives in an amount of 0.5 mol or less based on 1 mol of M^{I}X.

As the phosphor, it is also preferred to use a rare earth activated alkaline earth metal fluoride halide stimulable phosphor represented by the following formula (II):
M^{II} FX:aLn (II)
in which M^{II} is at least one alkaline earth metal selected from the group consisting of Ba, Sr and Ca; Ln is at least one rare earth metal selected from the group consisting of Ce, Pr, Sm, Eu, Tb, Dy, Ho, Nd, Er, Tm and Yb; X is at least one halogen selected from the group consisting of Cl, Br and I; and z is a number satisfying the condition of 0<z≦0.2.

In the formula (II), M^{II} preferably comprises Ba more than half of the total amount of M^{II}, and Ln is preferably Eu or Ce. The M^{II}FX in the formula (II) represents a matrix crystal structure of BaFX type, and it by no means indicates stoichiometrical composition of the phosphor. Accordingly, the molar ratio of F:X is not always 1:1. It is generally preferred that the BaFX type crystal have many F⁺(X⁻) centers corresponding to vacant lattice points of X⁻ions since they increase the efficiency of stimulated emission in the wavelength region of 600 to 700 nm. In that case, F is often slightly in excess of X.

Although omitted from the formula (II), one or more additives such as bA, wN^{I}, xN^{II} and yN^{III} may be incorporated into the phosphor of the formula (II), if needed. In the above, A is a metal oxide such as Al₂O₃, SiO₂ or ZrO₂. In order to prevent M^{II}FX particles from sintering, the metal oxide preferably has low reactivity with M^{II}FX and the primary particles of the oxide are preferably super-fine particles of 0.1 μm or less diameter. In the above, N^{I} is a compound of at least one alkali metal selected from the group consisting of Li, Na, K, Rb and Cs; N^{II} is a compound of alkaline earth metal(s) Mg and/or Be; and N^{III} is a compound of at least one trivalent metal selected from the group consisting of Al, Ga, In, Tl, Sc, Y, La, Gd and Lu. The metal compounds are preferably halides, but are not restricted to them.

In the above, b, w, x and y represent amounts of the additives incorporated into the starting materials, provided that the amount of M^{II}FX is assumed to be 1 mol. They are numbers satisfying the conditions of 0≦b≦0.5, 0≦w≦2, 0≦x≦0.3 and 0≦y≦0.3, respectively. These numbers by no means represent the contents in the resultant phosphor because the additives decrease during the step of deposition. Some additives remain in the resultant phosphor as they are added to the materials, but the others react with M^{II}FX or are involved in the matrix.

In addition, the phosphor of the formula (II) may further comprise Zn and Cd compounds; metal oxides such as TiO₂, BeO, MgO, CaO, SrO, BaO, ZnO, Y₂O₃, La₂O₃, In₂O₃, GeO₂, SnO₂, Nb₂O₅, Ta₂O₅ and ThO₂; Zr and Sc compounds; B compounds; As and Si compounds; tetrafluoro-borate compounds; hexafluoro compounds such as monovalent or divalent salts of hexafluorosilicic-acid, hexafluoro-titanic acid and hexafluorozirconic acid; or compounds of transition metals such as V, Cr, Mn, Fe, Co and Ni. The phosphor employable in the invention is not restricted to the above-mentioned materials, and any phosphor that can be essentially regarded as rare earth activated alkaline earth metal fluoride halide stimulable phosphor can be used.

The phosphor in the invention is not restricted to an energy-storing phosphor, either. It may be a phosphor which absorbs radiation such as X-ray and gives spontaneous emission in the ultraviolet or visible resin off. Examples of the phosphors include phosphors of LnTaO₄:(Nb, Gd) type, Ln₂SiO₅:Ce type and LnOX:Tm type (Ln is a rare earth element); CsX (X is a halogen); Gd₂O₂S:Tb; Gd₂O₂S:Pr,Ce; ZnWO₄; LuAlO₃:Ce; Gd₃Ga₅O₁₂:Cr,Ce; and HfO₂.

In the case where the vapor-deposited layer is formed by multi-vapor deposition (co-deposition), at least two evaporation sources are used. One of the sources contains a matrix component of the phosphor, and the other contains an activator component. The multivapor deposition is preferred because the vaporization rate of each source can be independently controlled even if these components have very different vapor pressures. According to the composition of the desired phosphor, each source may consist of the matrix component or the activator component only or otherwise may be a mixture thereof with additives. Three or more sources may be used. For example, in addition to the above sources, an evaporation source containing additives may be used.

The matrix component of the phosphor may be either the matrix compound itself or a mixture of two or more substances that react with each other to produce the matrix compound. The activator component is generally a compound containing an activating element, for example, a halide or oxide of the activating element.

If the activator element is Eu, the Eu-containing compound of the activator component preferably contains Eu²⁺ in a content of 70% or more by molar ratio because the desired stimulated emission (or instant emission) is emitted from the phosphor activated by Eu²⁺ although the Eu-containing compound generally contains both Eu²⁺ and Eu³⁺. The Eu-containing compound preferably is EuBrₘ in which m is a number preferably satisfying the condition of 2.0≦m≦2.3. In principle, the value of m should be 2.0, but if so, oxygen is liable to invade the compound. The compound is, therefore, practically stable when m is approximately 2.2. It is possible to use EuBr₂ from which oxygen is removed by melting in a Br gas atmosphere.

The evaporation source preferably has a water content of not more than 0.5 wt. %. For preventing the source from bumping, it is particularly important to control the water content in the above low range if the component of matrix or activator is a hygroscopic substance such as EuBr or CsBr. The components are preferably dried by heating at 100 to 300° C. under reduced pressure. Otherwise, the components may be heated under dry atmosphere such as nitrogen gas atmosphere to melt at a temperature above the melting point for several minutes to several hours.

The evaporation source preferably has a relative density of preferably 80% or more, more preferably 90% or more. Here, the “relative density” means a ratio of a density of the evaporation source to the inherent density of the phosphor or components thereof. If the relative density is so low that the source is in the form of powder, the powder is often sprinkled during vaporization and/or the source is liable to be evaporated so unevenly that the deposited phosphor film (layer) has uneven thickness. Therefore, for ensuring stable evaporation and deposition, the relative density preferably is in the particular range. In order to control the density in the above range, generally the material in the form of powder is pressed with a pressure of 20 Mpa or more or otherwise is heated to melt at a temperature above the melting point to shape a tablet. The evaporation source, however, is not always required to be in the shape of a tablet.

The evaporation source, particularly the source containing the matrix component, can contain impurities of alkali metal (alkali metals other than ones constituting the phosphor) preferably in a content of 10 ppm or less and impurities of alkaline earth metal (alkaline earth metals other than ones constituting the phosphor) preferably in a content of 5 ppm or less (by weight). This is important particularly when the phosphor is an alkali metal halide stimulable phosphor represented by the formula (I). The preferred evaporation source can be prepared from components containing the impurities as little as possible.

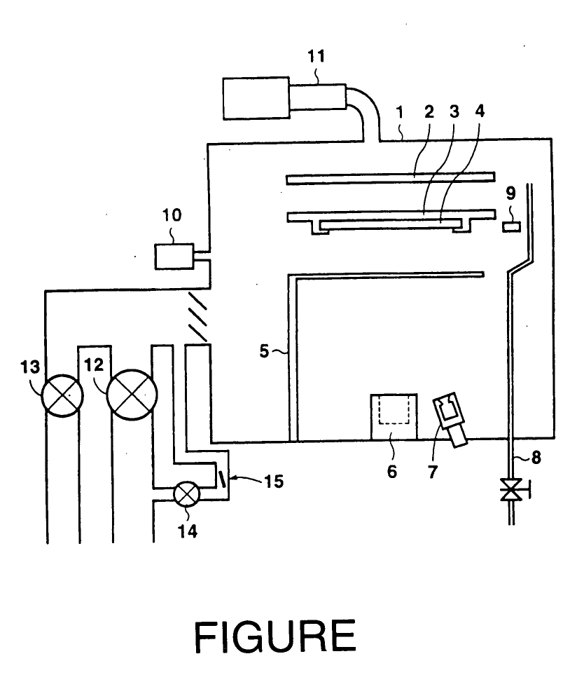

According to the invention, the deposited film can be formed on the substrate in a deposition apparatus, for example, shown in FIG. 1.

FIG. 1 is a sectional view schematically illustrating an example of the deposition apparatus used in the invention. The apparatus shown in FIG. 1 comprises a chamber 1, a substrate heater 2, a substrate holder 3, a shutter 5, resistance heaters 6 and 7, an intake pipe 8, a deposition rate monitor 9, a vacuum gauge 10, a gas analyzer 11, a main exhaust valve 12, an auxiliary exhaust valve 13, a by-path exhaust valve 14, and an exhaust control valve 15 (e.g., of butterfly type).

In the apparatus shown in FIG. 1, two or more evaporation sources are placed at predetermined positions on the resistance heaters 6 and 7. The substrate 4 is mounted on the substrate holder 3. After the chamber 1 is pre-evacuated through the auxiliary exhaust valve 13, the auxiliary exhaust valve 13 is closed and then the chamber 1 is further evacuated through the main exhaust valve 12 to make the inner pressure in the range of 1×10⁻⁵ to 1×10⁻² Pa. Into the thus highly evacuated chamber 1, an inert gas such as Ar, Ne or N₂ gas is introduced through the intake pipe 8 so that the inner pressure may be a medium vacuum in the range of 0.05 to 10 Pa. The degree of vacuum in the chamber 1 is monitored with the vacuum gauge 10. The chamber 1 can be evacuated by means of an optional combination of, for example, a rotary pump, a turbo molecular pump, a cryo pump, a diffusion pump and a mechanical buster.

It is characteristic of the present invention to continue evacuating the chamber 1 through the main exhaust valve 12, the by-path exhaust valve 14 and the exhaust control valve 15 and, at the same time, to continue introducing the inert gas through the intake pipe 8 during the deposition. The inert gas is introduced at the flow rate of Vn (mL/minute) satisfying the condition of:
0.002≦Vn/Vc≦20
in which Vc is a volume (L) of the chamber 1.

Gas components (active gas components such as H₂O, O₂ and H₂ gases) adsorbed on the inner wall of the chamber 1 are released when the chamber 1 is evacuated. If the ratio Vn/Vc is smaller than 0.002, the released gas components cannot be fully exhausted and consequently the resultant deposited film (layer) has poor emission characteristics. On the other hand, if the ratio Vn/Vc is larger than 20, the introduced gas makes a stream in the chamber 1 and the stream of the introduced gas affects flows of vapors from the evaporation sources to impair the crystallization of the deposited layer.

The inert gas is preferably introduced at the flow of Vn (mL/minute) satisfying the condition of:
0.005≦Vn/Vc≦10.

The degree of vacuum in the chamber 1 during the deposition is kept generally in the range of 0.05 to 10 Pa, preferably in the range of 0.1 to 3 Pa. The introduced inert gas preferably is Ar gas.

The inert gas is continuously introduced into the chamber 1 at a constant flow. On the other hand, at the same time, the chamber 1 is continuously evacuated so that the degree of vacuum may be kept within the above range. In this way, even if the active gas components beforehand adsorbed on the inner wall of the chamber 1 are continuously released, the partial pressure of each released gas component can be kept enough small. In the invention, the partial pressure of H₂O in the apparatus preferably is not more than 2×10⁻² Pa. The partial pressure of O₂ preferably is not more than 1×10⁻³ Pa. The partial pressure of H₂ preferably is not more than 1×10⁻² Pa. These partial pressures of H₂O, O₂ and H₂ are those of amu (atomic mass unit)=18, amu=32 and amu=2, respectively. The gas components are detected by means of the gas analyzer 11, and their partial pressures are determined according to the mass spectrometry (mass filter), as described after in Examples.

During the deposition, the substrate 4 may be heated, if needed, by means of the substrate heater 2 placed on the back side (the opposite side to the face which the vapor is deposited on). The substrate 4 may be cooled, or may be rotated and/or revolved.

For heating the evaporation sources, electric currents are supplied to the resistance heaters 6, 7. The sources of phosphor components are thus heated, vaporized, sprinkled and reacted with each other to form the phosphor, which is deposited on the substrate. When the evaporation sources are heated enough to vaporize, the shutter 5 is opened. The vaporized substances are reacted with each other to form the phosphor, which is deposited and accumulated on the substrate 4.

The deposition rate of each vaporized phosphor component can be detected by means of the monitor 9 at any time during the deposition. The deposition rate can be controlled by adjusting the electric currents supplied to the heaters 6, 7, and generally is in the range of 0.1 to 1,000 μm/minute, preferably in the range of 1 to 100 μm/minute.

The heating by means of the resistance heaters may be repeated twice or more to form two or more phosphor layers. After the deposition procedure is complete, the deposited layer may be subjected to heating treatment (annealing treatment).

Before preparing the above deposited film (layer) of phosphor, another deposited film (layer) consisting of the phosphor matrix alone may be beforehand formed. If so, columnar crystals of the phosphor can be formed on well-shaped columnar crystals of the matrix. Since each columnar crystal of the phosphor one-to-one corresponds to that of the matrix, the phosphor layer consisting of well-shaped columnar crystals can be obtained. In the thus-formed layered films, the additives such as the activator contained in the phosphor-deposited film are diffused into the matrix alone-deposited film while they are heated during the deposition and/or during the heating treatment performed after the deposition, and consequently the interface between the films is not always clear.

In the case where the phosphor layer is produced by mono-vapor deposition, only one evaporation source containing the phosphor or a mixture of materials thereof is heated with a single resistance heater. The evaporation source is beforehand prepared so that it may contain the activator in a predetermined amount. Otherwise, in consideration of the gap of vapor pressures between the matrix components and the activator, the deposition procedure may be carried out while the matrix components are being supplied to the evaporation source.

The produced phosphor layer consists of a phosphor in the form of columnar crystals grown almost parallel to the thickness direction. The phosphor layer contains no binder and consists of the phosphor only, and there are cracks among the columnar crystals. The thickness of the phosphor layer depends on, for example, aimed characters of the panel, conditions and process of the deposition, but is normally in the range of 50 μm to 1 mm, preferably in the range of 200 to 700 μm.

The apparatus employable in the invention is not restricted to that shown in FIG. 1. The deposition method usable in the invention is also not restricted to the above-described resistance heating process, and various other known processes such as an electron beam-application process can be used. If the electron beam-application process is adopted, an electron beam generated by an electron gun is applied to an evaporation source. The accelerating voltage of the electron beam is preferably in the range of 1.5 to 5.0 kV.

It is not necessary for the substrate to be used as a support of the radiation image storage panel. For example, after formed on the substrate, the deposited film is peeled from the substrate and then laminated on a support with an adhesive to prepare the phosphor layer. Otherwise, the support (substrate) may be omitted.

It is preferred to place a protective film on the surface of the phosphor layer, so as to ensure good handling of the storage panel in transportation and to avoid deterioration. The protective film is preferably transparent so as not to prevent the stimulating rays from coming in or not to prevent the emission from coming out. Further, for protecting the panel from chemical deterioration and physical damage, the protective film preferably is chemically stable, physically strong, and of high moisture proof.

The protective film can be provided by coating the phosphor layer with a solution in which an organic polymer such as cellulose derivatives, polymethyl methacrylate or fluororesins soluble in organic solvents is dissolved in a solvent, by placing a beforehand prepared sheet for the protective film (e.g., a film of organic polymer such as polyethylene terephthalate, a transparent glass plate) on the phosphor film with an adhesive, or by depositing vapor of inorganic compounds on the phosphor film. Various additives may be dispersed in the protective film. Examples of the additives include light-scattering fine particles (e.g., particles of magnesium oxide, zinc oxide, titanium dioxide and alumina), a slipping agent (e.g., powders of perfluoroolefin resin and silicone resin) and a crosslinking agent (e.g., polyisocyanate). The thickness of the protective film is generally in the range of about 0.1 to 20 μm if the film is made of polymer material or in the range of about 100 to 1,000 μm if the film is made of inorganic material such as glass.

For enhancing the resistance to stain, a fluororesin layer may be further provided on the protective film. The fluororesin layer can be form by coating the surface of the protective film with a solution in which a fluororesin is dissolved (or dispersed) in an organic solvent, and drying the applied solution. The fluororesin may be used singly, but a mixture of the fluororesin and a film-forming resin is normally employed. In the mixture, an oligomer having polysiloxane structure or perfluoroalkyl group can be further added. In the fluororesin layer, fine particle filler may be incorporated to reduce blotches caused by interference and to improve the quality of the resultant image. The thickness of the fluororesin layer is generally in the range of 0.5 to 20 μm. For forming the fluororesin layer, additives such as a crosslinking agent, a film-hardening agent and an anti-yellowing agent can be used. In particular, the cross-linking agent is advantageously employed to improve durability of the fluororesin layer.

Thus, a radiation image storage panel of the invention can be prepared. The storage panel of the invention may be in known various structures. For example, in order to improve the sharpness of the resultant image, at least one of the films (layers) may be colored with a colorant which does not absorb the stimulated emission but the stimulating ray.

In the following examples, the partial pressures of H2O, O₂ and H₂ were determined according to the mass spectrometry. The atmosphere in the apparatus was measured by means of a gas analyzer (mass filter, RGA300, STANFORD RESEARCH SYSTEM). The partial pressures of H₂O, O₂ and H₂ are those of amu=18, amu=32 and amu=2, respectively. The degree of vacuum in the apparatus was measured by means of an ionization gauge (GI-TL3RY, ULVAC, Inc.).

### EXAMPLE 1

(1) Evaporation Source

As the evaporation sources, powdery cesium bromide (CsBr, purity: 4N or more) and powdery europium bromide (EuBr₂, purity: 3N or more) were prepared. Each of them was analyzed according to ICP-MS method (Inductively Coupled Plasma Mass Spectrometry), to determine the contents of impurities. The CsBr powder contained alkali metals (Li, Na, K, Rb) other than Cs in amounts of 10 ppm or less and other elements such as alkaline earth metals (Mg, Ca, Sr, Ba) in amounts of 2 ppm or less. The EuBr₂ powder contained rare earth elements other than Eu in amounts of 20 ppm or less and other elements in amounts of 10 ppm or less. The powders were very hygroscopic, and hence were stored in a desiccator keeping a dry condition whose dew point was −20 ° C. or below. Immediately before used, they were taken out of the desiccator.

(2) Preparation of phosphor layer

A synthetic quartz substrate (support) 4 was washed successively with an aqueous alkaline solution, purified water and IPA (isopropyl alcohol), and then mounted to a substrate.holder 3 in a deposition apparatus shown in FIG. 1. The CsBr and EuBr₂ evaporation sources were placed in crucibles on the resistance heaters 6 and 7, respectively. The distance between the substrate 4 and each source was 15 cm. The chamber 1 (volume: 1,000 L) was then evacuated through the main exhaust valve 12, to make the inner pressure 1×10⁻³ Pa by means a combination of a rotary pump, a mechanical buster and a diffusion pump. In addition, a cryo pump is used to remove moisture in the chamber. The main exhaust valve 12 was then closed, and the by-path exhaust valve 14 provided on a by-path (diameter: 100 mm, length: 1 m) was opened. The exhaust control valve 15 was half opened. Ar gas was then introduced through the intake pipe 8 at a flow rate of 10 mL/min., so that the degree of vacuum was set at 1.1 Pa. Subsequently, the substrate 4 was heated to 100° C. by means of the substrate heater 2.

With the shutter 5 closed, the evaporation sources were heated by means of the resistance heaters 6 and 7. The shutter 5 covering the CsBr source was first opened so that CsBr was alone accumulated on the substrate 4 to form a layer of phosphor matrix. After 3 minutes, the shutter 5 covering the EuBr₂ source was then opened so that CsBr:Eu stimulable phosphor was accumulated on the matrix layer at the rate of 8 μm/min. During the deposition, the electric currents supplied to the heaters were controlled so that the molar ratio of Eu/Cs in the stimulable phosphor might be 0.003/1.

After the evaporation-deposition was complete, the inner pressure was returned to atmospheric pressure and then the substrate was taken out of the apparatus. On the substrate, a deposited film (thickness: approx. 500 μm, area: 10 cm×10 cm) consisting of columnar phosphor crystals aligned densely and almost perpendicularly was formed. Thus, a radiation image storage panel of the invention comprising the support and the phosphor layer was produced by multi-vapor deposition (co-deposition).

### EXAMPLE 2

The procedure of Example 1 was repeated except that the exhaust control valve 15 was left fully opened and that Ar gas was introduced at a flow rate of 30 mL/min. to keep the degree of vacuum at 1.1 Pa. Thus, a radiation image storage panel of the invention was produced.

### EXAMPLE 3

The procedure of Example 1 was repeated except that an apparatus having a chamber of 300 L was used, that the chamber was evacuated by means a combination of a rotary pump, a mechanical buster and a turbo molecular pump, that the main exhaust valve was left fully opened, and that Ar gas was introduced at a flow rate of 600 mL/min. to keep the degree of vacuum at 0.8 Pa. Thus, a radiation image storage panel of the invention was produced.

### EXAMPLE 4

The procedure of Example 1 was repeated except that an apparatus having a chamber of 710 L was used and that Ar gas was introduced at a flow rate of 20 mL/min., by controlling the exhaust control valve 15, to keep the degree of vacuum at 1.0 Pa. Thus, a radiation image storage panel of the invention was produced.

### EXAMPLE 5

The procedure of Example 1 was repeated except that an apparatus having a chamber of 1,500 L was used and that Ar gas was introduced at a flow rate of 37 mL/min., by controlling the exhaust control valve 15, to keep the degree of vacuum at 1.0 Pa. Thus, a radiation image storage panel of the invention was produced.

### EXAMPLE 6

The procedure of Example 1 was repeated except that an apparatus having a chamber of 710 L was used and that Ar gas was introduced at a flow rate of 14 mL/min., by controlling the exhaust control valve 15, to keep the degree of vacuum at 0.5 Pa. Thus, a radiation image storage panel of the invention was produced.

### EXAMPLE 7

The procedure of Example 1 was repeated except that an apparatus having a chamber of 1,500 L was used and that Ar gas was introduced at a flow rate of 19 mL/min., by controlling the exhaust control valve 15, to keep the degree of vacuum at 0.5 Pa. Thus, a radiation image storage panel of the invention was produced.

### COMPARISON EXAMPLE 1

The procedure of Example 1 was repeated except that the chamber was evacuated by means a combination of a rotary pump and a mechanical buster, that neither exhaust diffusion pump nor cryo pump for removing moisture was used, that the auxiliary exhaust valve was left opened, and that Ar gas was introduced at a flow rate of 1 mL/min. to keep the degree of vacuum at 1.1 Pa. Thus, a radiation image storage panel for comparison was produced.

[Evaluation of Radiation Image Storage Panel]

The sensitivity of each produced storage panel was evaluated in the following manner. Each radiation image storage panel was encased in a room light-shielding cassette and then exposed to X-rays (voltage: 80 kVp) in the amount of 10 mR. The storage panel was then taken out of the cassette and excited with a semiconductor laser beam (wavelength: 660 nm), and sequentially the emitted stimulated emission was detected by a photomultiplier. On the basis of the detected stimulated emission intensity, the sensitivity was evaluated (and converted into a relative value based on the intensity of Comparison Example 1).

The results are set forth in Table 1. In Table 1, the partial pressures are also shown.

TABLE 1

| | | | Degree | Partial pressure | | | |
|---|---|---|---|---|---|---|---|
| | Vn | | of vacuum | H₂O | O₂ | H₂ | Sensi- |
| Ex. | (mL/min.) | Vn/Vc | (Pa) | (10⁻³ Pa) | (10⁻⁴ Pa) | (10⁻³ Pa) | tivity |
| Ex. 1 | 10 | 0.01 | 1.1 | 8.3 | 6.2 | 5.9 | 134 |
| Ex. 2 | 30 | 0.03 | 1.1 | 4.5 | 3.4 | 3.0 | 153 |
| Ex. 3 | 600 | 2 | 0.8 | 0.82 | 0.75 | 0.52 | 145 |
| Ex. 4 | 20 | 0.028 | 1.0 | 4.2 | 4.1 | 3.3 | 157 |
| Ex. 5 | 37 | 0.025 | 1.0 | 4.4 | 4.5 | 3.8 | 161 |
| Ex. 6 | 14 | 0.020 | 0.5 | 3.4 | 3.0 | 2.3 | 165 |
| Ex. 7 | 19 | 0.013 | 0.5 | 4.0 | 3.7 | 2.9 | 168 |
| Com. 1 | 1 | 0.001 | 1.1 | 98 | 19 | 29 | 100 |

The results shown in Table 1 clearly indicate that the radiation image storage panels of the invention (Examples 1 to 5), which were produced by conducting the deposition while Ar gas was continuously introduced at a flow rate in the specific range, have higher sensitivities than the storage panel for comparison (Comparison Example 1), which was produced by conducting the deposition under a small flow of Ar gas. Further, according to the results shown in Table 1, the partial pressures of H₂O, O₂ and H₂ can be kept at low levels in the invention.

The present invention makes it possible to control the partial pressures of active gas components below enough low levels even if the deposition is performed under a medium degree of vacuum, and thereby gives a phosphor layer excellent in the amount of emission. Accordingly, the invention provides a radiation image storage panel giving a radiation image of high quality with high sensitivity.

1. A process for preparing a radiation image storage panel which comprises the steps of heating an evaporation source containing a phosphor or components thereof in a deposition apparatus to produce a vapor thereof and depositing the vapor on a substrate to form a phosphor layer thereon, wherein the steps are performed under such condition that an inert gas is introduced into the apparatus at a flow rate of Vn satisfying the following condition, while the apparatus is being evacuated,
0.002≦Vn/Vc≦20
in which Vn is a flow rate of the gas introduced into the apparatus in terms of mL/min., and Vc is a volume of the apparatus in terms of L.

2. The process of claim 1, wherein the steps are performed in the deposition apparatus at a pressure in the range of 0.05 to 10 Pa.

3. The process of claim 1, wherein the flow rate Vn of the inert gas satisfies the condition of:
0.005≦Vn/Vc≦10.

4. The process of claim 1, wherein the inert gas is Ar gas.

5. The process of claim 1, wherein the steps are performed at a H₂O partial pressure of 2×10⁻³ Pa or less.

6. The process of claim 1, wherein the steps are performed at an O₂ partial pressure of 1×10⁻³ Pa or less.

7. The process of claim 1, wherein the steps are performed at a H₂ partial pressure of 1×10⁻² Pa or less.

8. The process of claim 1, wherein the heating step is conducted utilizing a resistance-heater.

9. The process of claim 1, wherein the phosphor is a stimulable alkali metal halide phosphor having the following formula (I):
M^{I}X.aM^{II}X′₂.bM^{III}X″₃:zA (I)
in which M^{I} is at least one alkali metal selected from the group consisting of Li, Na, K, Rb and Cs; M^{II} is at least one alkaline earth metal or divalent metal selected from the group consisting of Be, Mg, Ca, Sr, Ba, Ni, Cu, Zn and Cd; M^{III} is at least one rare earth element or trivalent metal selected from the group consisting of Sc, Y, La, Ce, Pr, Nd, Pm, Sm, Eu, Gd, Tb, Dy, Ho, Er, Tm, Yb, Lu, Al, Ga and In; each of X, X′ and X″ is independently at least one halogen selected from the group consisting of F, Cl, Br and I; A is at least one rare earth element or metal selected from the group consisting of Y, Ce, Pr, Nd, Sm, Eu, Gd, Tb, Dy, Ho, Er, Tm, Yb, Lu, Na, Mg, Cu, Ag, Tl and Bi; and a, b and z are numbers satisfying the conditions of 0≦a<0.5, 0≦b<0.5 and 0<z<1.0, respectively.

10. The process of claim 9, wherein M^{I}, X and A in the formula (I) are Cs, Br and Eu, respectively, and z in the formula (I) is a number satisfying the condition of 1×10⁻⁴≦z≦0.1.
